(19) United States
(12) Patent Application Publication
(10) Pub. No.: US 2025/0338505 A1
(43) Pub. Date: Oct. 30, 2025

(54) ORBITAL HALL EFFECT MAGNETIC DEVICE AND METHOD FOR MANUFACTURING SUCH A DEVICE

(71) Applicants: COMMISSARIAT A L'ENERGIE ATOMIQUE ET AUX ENERGIES ALTERNATIVES, PARIS (FR); UNIVERSITE GRENOBLE ALPES, SAINT MARTIN D'HÈRES (FR); CENTRE NATIONAL DE LA RECHERCHE SCIENTIFIQUE, PARIS (FR); INSTITUT POLYTECHNIQUE DE GRENOBLE, GRENOBLE (FR)

(72) Inventors: Bernard VIALA, GRENOBLE CEDEX 09 (FR); Kévin GARELLO, GRENOBLE CEDEX 09 (FR)

(21) Appl. No.: 19/194,627

(22) Filed: Apr. 30, 2025

(30) Foreign Application Priority Data
Apr. 30, 2024 (FR) FR2404522

(51) Int. Cl. H10B 61/00; H10N 50/01; H10N 50/10

(52) U.S. Cl. CPC H10B 61/20; H10N 50/01; H10N 50/10

(57) ABSTRACT

A device includes a magnetic tunnel junction; a conductive spacer with low spin-orbit coupling and high mean orbital moment diffusion length; and a conductive track able to generate an orbital moment current from a charge current and having a weak spin-orbit coupling.

### CROSS-REFERENCE TO RELATED APPLICATIONS

This application claims priority to French Patent Application No. 2404522, filed Apr. 30, 2024, the entire content of which is incorporated herein by reference in its entirety.

### FIELD

The technical field of the invention is that of magnetic devices such as a memory or a magnetic field sensor, and more particularly magnetic devices making use of the Orbital Hall Effect (“OHE”).

### BACKGROUND

Non-volatile magnetic memories use, for example, a Magnetic Tunnel Junction (“MTJ”) made up of two magnetic layers separated by a non-magnetic insulating layer. One of the magnetic layers is referred to as a “trapped layer” or “reference layer” because it has a fixed magnetisation. The other magnetic layer is referred to as a “free layer” or “storage layer” because it has a variable magnetisation that can take on distinct values or orientations. The non-magnetic insulating layer is referred to as a “tunnel barrier” because it acts as a tunnel barrier during electron transport between both magnetic layers. The relative orientation of magnetisation of the free layer with respect to magnetisation of the reference layer enables information to be stored. The stored information (i.e. the orientation of one magnetisation relative to the other) can be read from the difference in resistance of the tunnel junction. For example, a parallel configuration of magnetisations corresponds to a state of minimum electrical resistance and, for example, a low state, i.e. a data bit “0”. The anti-parallel configuration of magnetisations corresponds to a state of maximum resistance and, for example, a high state, i.e. a data bit “1”. The relative difference is expressed as a percentage of Tunnel MagnetoResistance (TMR), which is usually in the order of 100% to 150% for usual so-called “top pinned” junctions and in the order of 150% to 200% for usual “bottom pinned” junctions. The trapped and free layers most often have magnetisation orientations that are perpendicular to the layer plane. This is known as a perpendicular magnetic Tunnel Junction or “pMTJ”.

Magnetic tunnel junctions are also known to be used as magnetic field sensors.

A first generation of magnetic devices (which can be used as magnetic memories or sensors) relies on a Spin Torque Transfer effect (STT) or Spin Transfer to exert a torque on magnetisation of the free layer. Spin transfer is based on the flow of an electric current through the tunnel junction. The magnetic tunnel junction is therefore usually connected to two terminals.

A second generation of magnetic devices is based on a Spin-Orbit Torque effect (SOT). In addition to the magnetic tunnel junction, a spin-orbit device includes a write track, also referred to as a spin-orbit track, most often made from a heavy transition metal such as Pt or β-W. The spin-orbit effect is a phenomenon that enables torque to be transmitted at an interface. The spin-orbit track is therefore disposed directly in contact with the free layer of the magnetic tunnel junction. The flow of an electric current in the spin-orbit track, and not through the tunnel junction, generates a spin current (different from an electron current), referred to as the spin Hall effect (SHE), which can exert a torque on magnetisation of the free layer. The spin-orbit effect offers the advantage of separating flow paths for the current performing reading (and flowing through the tunnel junction) from the write current (only flowing in the spin-orbit track). Unlike devices based on spin transfer, devices based on the spin-orbit torque require three terminals. Two of these connect the spin-orbit track, to exert a torque on magnetisation of the free layer (referred to as writing), and a third one connects the tunnel junction, opposite to the spin-orbit track, to perform reading of the magnetic tunnel junction state.

Although less compact than spin transfer devices, spin-orbit devices offer greater endurance because the electrical write current only travels the spin-orbit track and does not pass through the tunnel barrier (this has only the read current passing therethrough, which is always weaker than the write current). They can also be faster because their spin-orbit write time can be shorter (between 0.3 ns and 1 ms, for example) than the spin transfer effect write time (which is generally between 10 ns and 100 ns). Finally, spin-orbit devices are provided with better energy performance (in terms of power consumption per junction). These advantages mean that spin-orbit devices, and the resulting random access memories (called “SOT-MRAM” for “SOT Magnetic Random Access Memory”), can be used for embedded or “cache” type applications (memory that a microprocessor accesses more quickly and more frequently during calculations). For example, SOT-MRAMs are intended to replace static random access memories such as embedded SRAMs, which currently have no alternative. However, the manufacturing methods for spin-orbit devices and SOT-MRAMs are more complex and have not yet been fully mastered.

An alternative to magnetic devices based on the conversion of a charge current (for example electrons) into a spin current is to make use of another form of current writing while retaining the advantage of a write path separate from the read path. The writing is done by converting the charge current into an orbital moment current which has a similar ability to the spin current to exert a torque on magnetisation of a magnetic layer. This is the Orbital Hall Effect (OHE), which differs from the spin Hall effect. Orbital Hall effect writing is a good candidate for improving characteristics of magnetic devices.

The structure of an orbital Hall-effect device is similar to that of a spin-orbit device, with the difference that the write track, also referred to as the “OT” (Orbital Torque) track, is a track configured to generate an orbital moment current from a charge current.

For example, US 2023/0309411 A1 discloses a magnetic device comprising a magnetic tunnel junction, a conductive track extending in a plane and able to generate an orbital moment current, and a thin conversion layer sandwiched between the tunnel junction and the conductive track. The thin conversion layer enables the orbital moment current from the conductive track to be converted into a spin current so that spins can exert a spin-orbit torque on the free layer of the magnetic tunnel junction.

An orbital Hall-effect device such as that set forth in the aforementioned document can be made by means of the methods used to make spin-orbit devices. However, as with spin-orbit devices and SOT-MRAMs, the methods for manufacturing orbital Hall effect devices are complex and have not yet been fully mastered.

There is therefore a need to provide a magnetic device which is simpler to make and which allows magnetisation to be controlled by the orbital Hall effect with a control efficiency at least equivalent to devices of prior art.

### SUMMARY

For this, an aspect of the invention relates to a magnetic device comprising:
a magnetic tunnel junction;
a conductive spacer; and
a conductive track,
   the conductive spacer extending as an extension of the magnetic tunnel junction in a direction perpendicular to a plane, the plane being referred to as the “layer plane”, the conductive spacer being disposed between the magnetic tunnel junction and the conductive track, the conductive spacer being in direct contact with the conductive track, the conductive track comprising at least one portion extending in parallel to the layer plane and directly against the conductive spacer, the conductive spacer having:
a mean spin-orbit coupling strictly lower than 136 eV;
a mean orbital moment diffusion length strictly greater than 10 nm;
a thickness lower than the mean orbital moment diffusion length,
   the conductive track being able to generate an orbital moment current from a charge current and having a spin-orbit coupling strictly lower than 136 eV.

By “magnetic tunnel junction”, it is meant a stack of layers comprising two magnetic layers separated by an insulating layer able to allow an electron current to flow by tunnel effect.

By “spacer” it is meant a layer for spacing the magnetic tunnel junction and the conductive track apart.

By “conductive”, it is meant having an electrical conductivity (preferably averaged over the volume of the element in question) greater than 10³ S/m and such as greater than 10⁴ S/m.

By “the conductive spacer extends as an extension of the magnetic tunnel junction”, it is meant that the magnetic tunnel junction and the spacer are delimited by a same flank. By “flank”, it is meant a surface extending perpendicularly to the layer plane.

By “direct contact”, it is meant contact without an intermediary.

By “thickness”, it is meant a dimension measured perpendicularly to the layer plane.

By “track”, it is meant a layer with a length and a width, measured in parallel to the layer plane, its length being greater than its width.

By “mean spin-orbit coupling of an element”, it is meant an average over the volume of the element of the spin-orbit coupling made over the entire volume of the spacer.

By “mean orbital moment diffusion length of an element”, it is meant an average over the volume of the element of the mean orbital moment diffusion length.

By “in parallel to” and “parallel”, it is meant parallel to within 20°, or even 10°, and desirably to within 5°. Similarly, by “perpendicularly” and “perpendicular”, it is meant perpendicular to within 20°, or even 10°, and desirably to within 5°.

By “charge current”, it is meant a charge carrier current, which may be an electron and/or hole current.

By “orbital moment diffusion length”, it is meant a characteristic displacement distance of the orbital moment when considering diffusion displacement. An example of an orbital moment diffusion length is given for titanium in document [Choi & al. “Observation of the orbital Hall effect in a light metal Ti”, Nature 2023, vol. 619, no. 7968, p. 52-56].

The magnetic device provides a system for controlling magnetisation of the magnetic tunnel junction by orbital Hall effect. The flow of a longitudinal charge current (i.e. parallel to the layer plane) in the conductive track creates a transverse orbital moment current (i.e. perpendicular to the layer plane) in the conductive track. The orbital moment current is then injected into the conductive spacer which is in contact with the conductive track. The spacer allows the orbital moment current to be propagated towards the magnetic stack to apply torque to magnetisation of the magnetic tunnel junction. Since the mean orbital moment diffusion length is greater than the spacer thickness, a significant portion of the orbital moment current passes through the spacer and can be injected at the tunnel junction. This orbital moment current can therefore exert a spin-orbit torque on a magnetisation of the tunnel junction. This orbital moment current makes it possible to control magnetisation of the tunnel junction in order to cause precession of the same and/or make it switch. The spacer therefore makes it possible to relocate the Orbital Hall Effect (OHE) of the conductive track.

The distancing offered by the spacer also allows stress relaxation on the manufacture of the conductive track. For example, it is possible to resort to materials whose manufacturing methods are not compatible with those of a tunnel junction in immediate proximity thereto.

Spin-orbit coupling promotes conversion of an electric charge current into a spin current. Without spin-orbit coupling, an electric charge current can theoretically be converted into an orbital moment current.

Weak spin-orbit coupling generates a weak or even negligible spin current and a strong or even dominant orbital moment current. A spin current and an orbital moment current can interact constructively and/or destructively with each other in a difficult to control way. This constructive/destructive interaction may depend on the materials considered for the conductive track and/or the spacer. It can also depend on the thickness of the spacer. Indeed, competition between spin and orbital moment currents can lead to a rapid reduction in total current as a function of distance. Reducing or even cancelling out these constructive/destructive interactions allows better control of the amplitude of the orbital moment current at the tunnel junction and therefore better control of the torque exerted on free magnetisation of this junction.

With respect to a device whose track (known as the “SOT” (Spin Orbit Torque) track) is able to generate a spin current from a charge current, the device of the invention has several advantages. To generate a spin current, materials usually considered have a spin-orbit coupling that can be greater than 680 eV, or 50 Ry (considering 1 Ry=13.6 eV). However, these materials generally have a low conductivity, in the order of 10² S/m. This low conductivity reduces energy efficiency of the resulting devices, but also means that very thin tracks have to be formed, with thicknesses lower than 10 nm and around 4 nm. These low thicknesses severely restrict the manufacture of such tracks, because without precise control of the etching depth of the devices, these tracks are generally cut out.

Materials used to form a track able to generate an orbital moment current are generally simpler to use. For example, they have a high electrical conductivity, making it possible to form thick conductive tracks, in the order of 100 nm, and therefore robust to etching (even if the etching depth is not well controlled).

Beneficially, the conductive spacer has a thickness greater than or equal to 20 nm.

Beneficially, the mean spin-orbit coupling of the conductive spacer is strictly lower than 13.6 eV.

Beneficially, the conductive track has a thickness strictly greater than 10 nm and such as greater than 50 nm.

Beneficially, the mean spin-orbit coupling of the conductive track is strictly lower than 13.6 eV.

Beneficially, the conductive track is able to convert at least 10% of the charge current into orbital moment current and in an embodiment at least 50% of the charge current into orbital moment current.

Beneficially, the device comprises a substrate. The magnetic tunnel junction is disposed between the conductive spacer and the substrate or the conductive spacer is disposed between the magnetic tunnel junction and the substrate.

Beneficially, the conductive spacer is in direct contact with the magnetic tunnel junction.

Beneficially, the device comprises an additional layer, referred to as the “conversion layer”, having a spin-orbit coupling greater than 680 eV, disposed between the magnetic tunnel junction and the conductive spacer, the conversion layer extending directly against the magnetic tunnel junction and directly against the conductive spacer.

Beneficially, the conversion layer has a thickness strictly lower than 10 nm.

The invention further relates to a method for manufacturing a magnetic device comprising the following steps of:
depositing a magnetic stack extending in parallel to a so-called “layer plane” and intended to form, after etching, a magnetic tunnel junction;
depositing a conductive layer onto the magnetic stack;
etching the conductive layer anisotropically to form a conductive spacer;
etching the magnetic stack to form a magnetic tunnel junction, etching being performed by employing the conductive spacer as an etch mask, the conductive spacer having, after etching of the magnetic stack:
   a mean spin-orbit coupling strictly lower than 136 eV;
   a mean orbital moment diffusion length strictly greater than 10 nm; and
   a thickness lower than the mean orbital moment diffusion length; and
forming a conductive track in direct contact with the conductive spacer from a material able to generate an orbital moment current from a charge current and having a spin-orbit coupling strictly equal to 136 eV, the conductive track comprising at least one portion extending in parallel to the layer plane and directly against the conductive spacer.

This method makes it possible to manufacture a magnetic device in which the spacer rests on the tunnel junction. This is called a “bottom pinned” configuration because it beneficially makes it possible to dispose one of the magnetic layers of the junction, which has a fixed magnetisation, at the bottom of the device.

Orbital moment currents can be degraded by the interfaces through which they pass, especially when the quality of these interfaces is not optimal. Once the spacer has been deposited onto the magnetic stack, it protects the surface state of the stack. As a result, the surface state of the magnetic stack (under the spacer) is not impacted by subsequent manufacturing steps (such as delimiting the magnetic stack). This surface state can therefore retain optimum quality. Thus, the injection of orbital moments into the magnetic stack is optimal. For example the stack has a surface state obtained when it is deposited and the conductive layer is deposited onto the magnetic stack in such a way as to retain the surface state of said stack. For example, the magnetic stack and the conductive layer are deposited consecutively under vacuum, without venting between both deposition operations. In this way, the surface state of the first magnetic layer is optimal.

The conductive track can also be made secondly, without being worried about degrading the interface between the tunnel junction and the spacer.

In addition, the protection offered by the spacer also makes it possible to protect the surface state of the stack in order to make it possible to clean a surface of the spacer to which the conductive track will be transferred. In this way, the interface between the conductive track and the spacer can also be of good quality, without degrading other interfaces.

The thickness of the spacer is only restricted by its mean orbital moment diffusion length, which imposes a maximum final thickness. Hence, the conductive layer can therefore have a substantial initial thickness, for example as great as is necessary to undergo aggressive manufacturing steps, such as polishing or etching, to obtain a suitably shaped conductive track.

At the end of this method, the stack and the spacer are delimited by one and the same flank.

Beneficially, the conductive layer has an initial thickness as a function of:
the thickness of the magnetic stack;
the etch rate of the magnetic stack;
the etch rate of the conductive layer; and
the mean orbital moment diffusion length of the conductive spacer after etching the magnetic stack,
the etch rate of the magnetic stack and the etch rate of the conductive layer being considered for identical etching conditions.

Beneficially, the conductive spacer has a lower etch rate than the etch rate of the magnetic stack, the etch rates of the conductive spacer and the magnetic stack being considered for identical etching conditions.

Beneficially, the conductive layer is a multi-layer comprising a first sub-layer and a second sub-layer, the second sub-layer being disposed between the first sub-layer and the magnetic stack, the first sub-layer having an etch rate lower than the etch rate of the magnetic stack and lower than the etch rate of the second sub-layer, the etch rates of the first and second sub-layers and of the magnetic stack being considered for identical etching conditions.

Beneficially, forming the conductive track comprises the sub-steps of:
depositing a dielectric layer covering the conductive spacer;
etching a part of the dielectric layer with stopping on the top of the conductive spacer so that the dielectric layer has a flank extending perpendicularly to the layer plane and disposed as an extension of a part of a flank of the conductive spacer;
depositing the conductive track partly against the dielectric layer and partly against the conductive spacer, the conductive track having two consecutive portions, one of the portions, referred to as the “parallel portion”, extending in parallel to the layer plane and directly against the conductive spacer, and the other of the portions, referred to as the “perpendicular portion”, extending perpendicularly to the layer plane and directly against the flank of the dielectric layer.

Beneficially, forming the conductive track comprises the sub-steps of:
depositing an insulating layer against a flank of the conductive spacer;
forming a dielectric layer extending against the insulating layer while leaving a portion of the conductive spacer cleared;
forming a first conductive terminal and a second conductive terminal on the dielectric layer, on either side of the spacer, the first and second terminals being spaced apart and separated from the spacer by the insulating layer;
depositing the conductive track so that it extends in parallel to the layer plane and against the cleared portion of the spacer, by electrically connecting the first and second terminals.

An aspect of the invention also relates to a method for manufacturing a magnetic device comprising the following steps of:
depositing a conductive layer extending in parallel to a so-called “layer plane”, the conductive layer having a mean spin-orbit coupling strictly lower than 136 eV, a mean orbital moment diffusion length strictly greater than 10 nm and being able to generate an orbital moment current from a charge current;
depositing a magnetic stack onto a conductive layer, the magnetic stack being intended to form a magnetic tunnel junction after etching;
etching the magnetic stack to form a magnetic tunnel junction, etching being made through an etch mask,
partially etching the conductive layer through the etch mask to form a conductive spacer and retaining part of the conductive layer forming a conductive track in direct contact with the conductive spacer, the thickness of the conductive spacer being lower than the mean orbital moment diffusion length, the conductive track comprising at least one portion extending in parallel to the layer plane and directly against the conductive spacer.

This method makes it possible to manufacture a magnetic device in which the magnetic tunnel junction rests on the spacer. This is a so-called “top pinned” configuration because it beneficially makes it possible to dispose of one of the magnetic layers of the junction, which has a fixed magnetisation, at the top of the device.

After being deposited onto the spacer, the magnetic stack protects the surface state between said stack and said spacer. As a result, the surface state between the magnetic stack and the spacer is not impacted by subsequent manufacturing steps (such as delimiting the magnetic stack). This surface state can therefore retain optimum quality. Thus, the injection of orbital moments into the magnetic stack is therefore optimal. For example, the conductive layer and the magnetic stack can be deposited in such a way as to retain the surface state between the spacer and the stack. For example, they are deposited consecutively under vacuum, without venting between both deposition operations.

The conductive track is formed from the same conductive layer as the spacer. This ensures a fault-free interface between both elements.

According to this method, said stack and the spacer are also delimited by one and the same flank.

The invention and its different applications will be better understood upon reading the following description and upon examining the accompanying figures.

### BRIEF DESCRIPTION OF THE FIGURES

The figures are set forth by way of indicating and in no way limiting purposes of the invention. Unless otherwise specified, a same element appearing in different figures has a single reference.

FIG. 1, FIG. 2, FIG. 3 and FIG. 4 show four embodiments of an orbital Hall effect magnetic device according to the invention.

FIG. 5, FIG. 6, FIG. 7, FIG. 8, FIG. 9 and FIG. 10 schematically show different steps in a manufacturing method for obtaining a magnetic device in a so-called “bottom pinned” configuration according to one or more embodiments.

FIG. 11 schematically shows a step of a manufacturing method for obtaining a magnetic device in a “top pinned” configuration according to one or more embodiments.

### DESCRIPTION

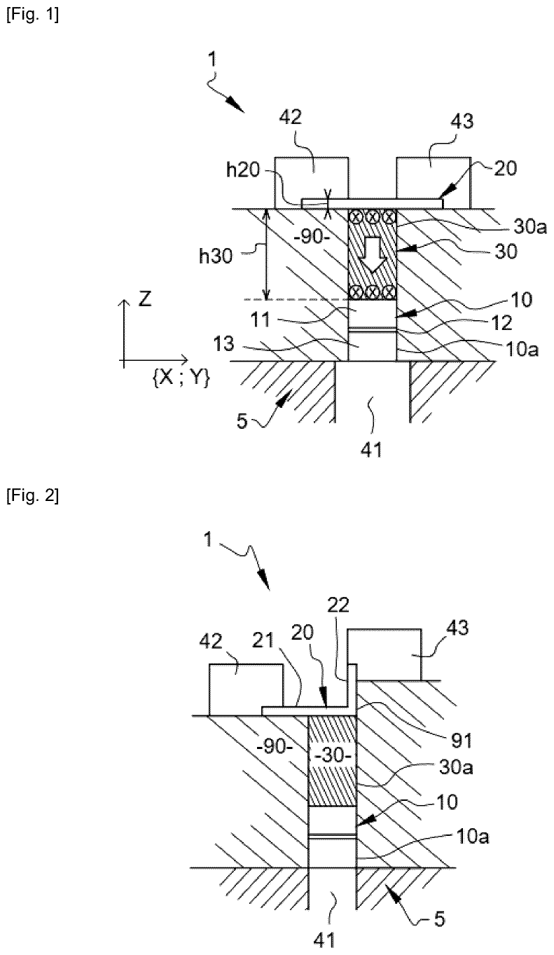

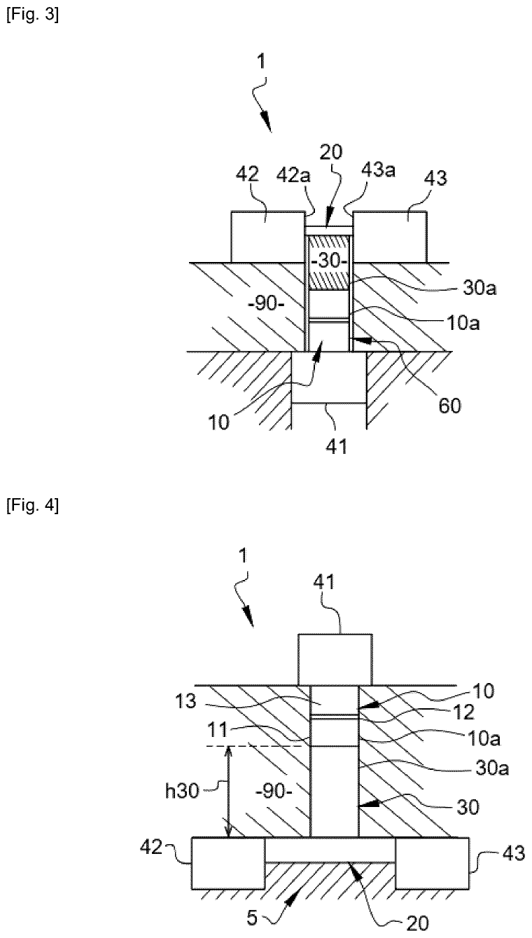

FIG. 1 schematically shows a first embodiment of a magnetic device 1 according to the invention. In particular, in this example, it is a non-volatile magnetic memory using an orbital moment current to perform magnetisation switching of the memory. In the remainder of the description, “device”, “magnetic device”, “memory” or “sensor” will be used interchangeably to describe this device. The teachings relating to this device and set forth within the scope of a non-volatile storage memory can be transposed to a magnetic field sensor. In the remainder of the description, when a spin-orbit coupling value is associated with a material, it is important to note that the spin-orbit coupling values mentioned are based on the 2p orbitals of atoms of the materials mentioned. These values are used to facilitate comparison between materials. This approach is adopted to provide a consistent and understandable reference within the scope of the invention.

In the embodiment of FIG. 1, the device 1 is connected to a first, conductive, terminal 41. This is, for example, a conductive via passing through a substrate 5 and opening out on the surface thereof. The first terminal 41 may be a conductive via, for example of copper, responsible for performing routing in an integrated circuit, for example at a so-called “back end of line” functional block. Alternatively, the first terminal 41 can be a plug, for example of tungsten, disposed on the via to block diffusion of species such as copper to the different levels of the back-end of line. Substrate 5 represents, for example, one level of the back-end of line. Substrate 5 is in an embodiment non-conductive, for example it is a semiconductor layer, for example of silicon, covered with one or more dielectric layers, for example of silicon oxide.

The substrate 5, and in particular its surface, defines a reference plane {X; Y} onto which the different layers of the device 1 are deposited. For this reason, this plane is also referred to as the “layer plane”. The axis Z, illustrated in FIG. 1, extends perpendicularly to the layer plane {X; Y} and may be referred to as “vertical axis”. The same convention of axes and planes is used in FIGS. 2 to 11 without repeating them.

The device 1 represented in FIG. 1 comprises:
a magnetic tunnel junction 10;
a conductive spacer 30; and
a conductive track 20.

The conductive spacer 30 is disposed between the tunnel junction 10 and the conductive track 20 to separate the same. In this embodiment, the magnetic tunnel junction 10 rests on the first terminal 41, with which it can be in electrical contact. The spacer 30 rests on the tunnel junction 10. Finally, the conductive track 20 rests on the spacer 30.

The spacer 30 extends as an extension of the magnetic tunnel junction 10 along the vertical axis Z. The spacer 30 and the junction 10 are herein delimited by a common flank 30, 10a which is, in this example, parallel to the vertical axis Z. By “flank”, it is meant a lateral surface 30a, 10a delimiting the perimeter of the spacer 30 and the junction 10. This bounding as an extension is a consequence of a method for manufacturing the device 1 and results, for example, from the delimitation by successive etching operations of both elements through a same etch mask. The stack of tunnel junction 10 and spacer 30 may therefore be cylindrical, ellipsoidal or parallelepipedal in shape, with a base resting on the first terminal 41.

The magnetic tunnel junction 10 of FIG. 1 comprises a first magnetic layer 11, referred to as the “free layer”, a second non-magnetic and insulating layer 12, referred to as the “tunnel barrier”, and a third magnetic layer 13, known as the “reference layer”. The magnetic layers 11, 13 extend in parallel to the layer plane.

The free layer 11 extends in parallel to the layer plane {X; Y}. It has a magnetisation and a magnetic anisotropy. The anisotropy of the free layer 11 is configured to stabilise magnetisation according to at least two distinct configurations. For example, anisotropy of the free layer 11 can spontaneously (and in the absence of an external field) orient magnetisation outside the layer plane {X; Y} and in an embodiment perpendicularly to the layer plane {X; Y} (this is known as perpendicular magnetic anisotropy). It can then be directed in parallel or antiparallel to the vertical axis Z. Alternatively, anisotropy of the free layer 11 may also be such that the magnetisation spontaneously orients itself in the layer plane {X; Y}. The magnetisation can also adopt a vortex or skyrmion configuration with a polarity outside the layer plane (i.e. a net magnetic moment outside the layer plane).

The free layer 11 can be made from Fe, Co, Ni or an alloy of these elements, for example CoFe, CoFeB or even NiFe.

The reference layer 13 also has a so-called “reference magnetisation”, and an anisotropy. The anisotropy of the reference layer 13 is in an embodiment configured so that the reference magnetisation has a predetermined configuration, for example along a fixed direction and oriented in the layer plane {X; Y} or oriented outside this plane. Anisotropy of the reference layer 13 is in an embodiment such that the reference magnetisation retains its configuration throughout the life time or use of the device 1. For this, the tunnel junction 10 may comprise an antiferromagnetic layer (not represented in FIG. 1), coupled to the reference layer 13, to enhance anisotropy of the reference layer 13. This may be a multi-layer of ferromagnetic layers coupled together in an antiparallel manner, a so-called “synthetic antiferromagnetic layer” or “SAF”.

The reference layer 13 can also be made from Fe, Co, Ni or an alloy of these elements, such as those mentioned above for the free layer 11, or from a multi-layer comprising alternating Co and Pt, for example.

The tunnel barrier 12 is configured to induce a tunnel effect when an electron current flows in the tunnel junction 10. This current is used, for example, to measure configuration of the magnetisation of the free layer 11 relative to the magnetisation of the reference layer 13. The tunnel barrier 12 is a non-magnetic insulating layer. It separates the free layer 11 from the reference layer 13 and in an embodiment extends in contact with these two layers 11, 13. It can be made from oxide, nitride or a combination of oxides and nitrides. For example, it may be MgO, MgAlxOy, AlOx, TiOx, HfOx, TaOx, AlN or ZnO.

The shape of the free 11 and reference 13 layers can contribute to the magnetic anisotropy of these layers by orienting their magnetisations outside the layer plane or, on the contrary, in the layer plane. Hence, delimiting the tunnel junction 10 can therefore have a significant impact on anisotropy of the resulting layers. The tunnel barrier 12 can also contribute to the magnetic anisotropy of the free layer 11 and/or the reference layer. When it is made of MgO, it can induce an interfacial anisotropy out of the plane in contact with CoFe or CoFeB layers. This interfacial anisotropy is beneficially used to orient magnetisation of the free layer 11 out of the layer plane {X; Y}.

The magnetic tunnel junction 10 enables the device 1 to function as a non-volatile magnetic memory or as a magnetic field sensor. Direct contact of the spacer 30 (or conversion layer) with the free layer 11 allows a torque to be applied to the magnetisation thereof.

The tunnel junction 10 may also include additional layers, not represented in FIG. 1. For example, this may be a “seed layer”, for promoting a crystal lattice upon growing the layers forming the tunnel junction 10. It can be made of Ta, Pt, W or even MgO.

In the embodiment of FIG. 1, the device 1 is in a so-called “bottom pinned” configuration (or arrangement). The tunnel junction 10 is disposed between the substrate 5 and the spacer 30. More precisely, this configuration may correspond to the arrangement of the magnetic layers 11, 13 of the tunnel junction 10, which may have an influence on the arrangement of the spacer 30 and the conductive track 20. In a bottom pinned configuration, the tunnel junction 10 rests on the reference layer 13. This means that the reference layer 13 is disposed between the free layer 11 and the substrate 5. The free layer 11 is therefore disposed on top of the tunnel junction 10, at which the spacer 30 rests.

The bottom-pinned configuration offers an advantage when delimiting the tunnel junction 10 and in particular the insulating layer by etching. Indeed, in an inverted so-called “top pinned” configuration, the free layer 11 is generally of low thickness and is close to the underlying substrate 5. When etched, etching residues can be deposited onto the walls of the junction 10 and short-circuit the tunnel barrier 12. In contrast, in the bottom-pinned configuration, the reference layer 13 is generally thicker and moves the tunnel barrier away from the underlying substrate 5. There is less risk of short-circuiting the tunnel barrier.

The spacer 30 is a non-magnetic conductor. It extends as an extension of the tunnel junction 10, along the vertical axis Z, to separate the conductive track 20 from the tunnel junction 10. It can therefore be used to manufacture the tunnel junction 10 and the conductive track 20 in distinct steps without compromising the junction 10 or the track 20. It is also adapted to transfer an orbital moment current generated by the track 20 to the tunnel junction 10 so that a magnetisation thereof can be controlled.

The spacer 30 comprises at least two faces, opposite to each other. One of both faces corresponds to the top of the spacer 30 (in the increasing direction along the vertical axis Z). The other of both faces, referred to as the “foot” and opposite to the top, faces the tunnel junction 10.

The conductive track 20 is in direct contact with the top of the spacer 30.

The spacer 30 may be in direct contact with the tunnel junction 10 and, for example, with the free layer 11 of the junction 10. By “direct contact”, it is meant that the spacer 30 and the free layer 11 share a common interface, there being no intermediate layer. As such, the foot of the spacer 30 (opposite to the top) is in direct contact with the free layer 11 of the junction 10. Thus, the orbital moment current is injected directly into the tunnel junction 10. In addition, the number of interfaces is restricted, enabling the injected current to be maximised.

Alternatively, the device 1 may comprise a conversion layer (not represented in the figures and discussed below). In this alternative, the spacer 30 (and more particularly the foot of the spacer 30) may be separated from the free layer 11 by the conversion layer.

The spacer 30 has a thickness h30, measured perpendicularly to the layer plane {X; Y} (which may also be referred to as the “height”).

Spacer 30 also has a mean orbital moment diffusion length δ₃₀. The mean orbital moment diffusion length δ (also referred to as the “mean diffusion length”) corresponds to a length that an orbital moment current can travel in a material before being significantly absorbed. The mean length corresponds to an average of the diffusion length over the volume of the spacer 30.

In order to act on magnetisation of the free layer 11, it is necessary for the spacer 30 to be able to transfer a substantial part of the orbital moment current generated by the track 20 to the tunnel junction 10 and in particular to the free layer 11. For this, the diffusion length δ₃₀ of the spacer 30 is strictly greater than the thickness h30 of the spacer 30. In other words, by limiting the thickness h30 of the spacer 30 to a value lower than the mean orbital moment diffusion length δ, part of the orbital moment current induced by the conductive track 20 is effectively transferred to the tunnel junction 10.

The mean diffusion length of spacer 30 is strictly greater than 10 nm. This means that the thickness of the spacer 30 can be 10 nm or more, to the limit of the mean diffusion length. A thickness h30 greater than or equal to 10 nm ensures sufficient distance between the tunnel junction 10 and the top of the spacer 30 to be able to form the conductive track, even with aggressive manufacturing steps and without the risk of damaging the tunnel junction 10. It also reduces the risk of migration of a species from the conductive track 20 to the tunnel junction 10 or vice versa. The greater the thickness h30 of the spacer 30, the lower the risk of damage or migration.

In an embodiment, the mean diffusion length of the spacer is greater than or equal to 20 nm or greater than or equal to 50 nm or greater than or equal to 100 nm, in order to obtain a spacer 30 with a large thickness, for example greater than 100 nm.

The spacer 30 also has a weak spin-orbit coupling. Thus, the propagation of orbital moment currents to junction 10 is only slightly perturbed by spin currents. By weak spin-orbit coupling, it is meant a coupling lower than 136 eV, or 10 Ry (the Rydberg unit, commonly used to express spin-orbit coupling, is equal to 13.6 eV). In an embodiment, the spin-orbit coupling of the spacer 30 is lower than 13.6 eV or 1 Ry.

Examples of materials with a low spin-orbit coupling and a long diffusion length are: titanium, vanadium, chromium, manganese, copper, zirconium, niobium, molybdenum, ruthenium, aluminium, polycrystalline silicon, alpha phase tungsten (called “α-W”, to be distinguished from the beta phase called “β-W”, which has too high a spin-orbit coupling). The spacer 30 can therefore be formed from one of these materials or an alloy of these materials. It is also interesting, to facilitate the manufacture of device 1, to make spacer 30 from a nitride of these materials or from a hardened alloy of these materials.

Titanium and titanium nitride materials have the advantage of being frequently used to form hard masks, so their use is well controlled.

Spacer 30 has the feature of being placed on paths used to perform writing and reading in device 1. Indeed, it is disposed on the orbital moment current path, during writing, and on the spin-polarised current path passing through junction 10 during reading. The spacer 30 is then beneficially selected to have a high electrical conductivity, equal to or beneficially greater than that of the conductive track 20. It is for example greater than or equal to 10³ S/m or in an embodiment greater than 10⁴ S/m.

The orbital moments do not allow a torque to be directly made on the magnetisation of the junction 10. One of two following mechanisms may be required. The action of the orbital moments on the magnetisation can be due to a spin-orbital entanglement with the spin moments and/or part of the orbital moment current is converted into a spin current in the junction 10, the spins applying a torque on magnetisation of the junction 10. The interest of such mechanisms is that they are not located in the immediate vicinity of the interface between the spacer 30 and the junction 10. The orbital moments can propagate in the volume of the magnetic layers and create a torque in the volume of these layers. It is of note that magnetic materials can also exhibit significant spin-orbit coupling which also tends to generate a spin current from part of the orbital moment current. This spin current can then apply a torque directly to the stack magnetisation.

In one alternative not illustrated, the device 1 can include a so-called “conversion layer”, whose role is to convert part of the orbital moment current into spin current. This conversion layer is made, for example, from a material with a high spin-orbit coupling (i.e. greater than 680 eV, i.e. 50 Ry). Placed in the path of the orbital moment currents, the conversion layer converts all or part of the orbital moment current into spin current, where spins can then apply a torque to magnetisation. The conversion layer can be placed anywhere between the conductive track 20 and the tunnel junction 10. However, it is desirable that it is placed between the spacer 30 and the tunnel junction 10. Thus, the conversion is performed just before the orbital and spin moment currents enter the tunnel junction 10. In addition, the spacer 30 may have a spin diffusion length which may be lower than the orbital moment diffusion length. Furthermore, between the spacer 30 and the tunnel junction 10, the conversion layer is also protected by the spacer 30, in the same way as the tunnel junction. The surface states of the conversion layer are therefore optimal.

The conversion layer extends, for example, in parallel to the layer plane and against the tunnel junction 10. The spacer 30 extends against the conversion layer.

The conversion layer is in an embodiment made from a material with a strong spin-orbit coupling, i.e. greater than or equal to 680 eV, i.e. 50 Ry. This conversion layer is made, for example, from a heavy metal such as platinum or tungsten carbide in its beta phase (noted “β-W”). Materials with high spin-orbit coupling generally have low electrical conductivity, for example in the order of 10² S/m or less. In order to retain a low electrical resistance within the device 1, the conversion layer is in an embodiment thin, i.e. lower than 10 nm thick. When it is made of platinum, for example, it is 8 nm thick. When it is made of β-W, for example, it is 4 nm thick.

The conductive track 20 extends over the spacer 30 and in direct contact with this spacer 30. In this example, it extends entirely parallel to the layer plane {X; Y}, overhanging the dielectric layer 90 surrounding the spacer 30. Stated differently, the device 1 is T-shaped, resting on the first terminal 41 with which it can be electrically connected.

The conductive track 20 is in direct contact with the spacer 30 and in particular directly against the top of the spacer 30. Thus, the spacer 30 separates the junction 10 from the track 20 and makes electrical contact between both of them (either directly between the junction 10 and the track 2, or by means of the conversion layer).

The conductive track 20 is connected to two conductive terminals 42, 43 for flowing an electron current in the track 20.

The conductive track 20 is configured to, when an electric current flows therethrough, induce an orbital moment current in the spacer 30. The orbital moment current is to be distinguished from a spin current or a current of spin-polarised electrons. In the present case, it is a current involving the displacement of charges the form of orbital moments. In the example in FIG. 1, the direction of the orbital moments is depicted as circled crosses. The flow of a longitudinal electric current in the conductive track 20, i.e. in parallel to the layer plane {X; Y}, generates a transverse orbital moment current, i.e. perpendicular to the layer plane. The direction of propagation of the orbital moment current is depicted as a thick arrow in FIG. 1. By virtue of the direct contact between the track 20 and the spacer 30, the orbital moment current propagates through the spacer 30 towards the tunnel junction 10.

The conductive track 20 is made from a material able to generate an orbital moment current from an electrical charge current. In particular, it is desired that the material in question has a sufficient rate of conversion of charge current into orbital moment current. The rate of conversion of charges into orbital moments is given per current unit and is therefore dimensionless. It is desirable to use materials for which the rate of conversion of an electrical charge current into an orbital moment current is greater than 1% and in an embodiment greater than or equal to 10%, or even greater than or equal to 50% and in an embodiment greater than or equal to 100%.

The track 20 is also made of a conductive material, i.e. with an electrical conductivity greater than 10³ S/m, or even greater than or equal to 10⁴ S/m, or even greater than or equal to 5-10⁴ S/m. In this way, resistive losses of the device 1 are low. The conductive track 20 can therefore be used to perform reading of the magnetic configuration of the tunnel junction 10, for example by spin transfer. The low resistance of the conductive track 20 also improves reading speed of the device 1.

The conductive track 20 has in an embodiment a large thickness h20, measured perpendicularly to the layer plane {X; Y}. Indeed, the efficiency of converting the charge current into orbital moment current increases with the thickness h20 of the conductive track 20. The conductive track 20 can therefore generate a large orbital moment current. In contrast, tracks used to generate spin currents (so-called “SOT tracks”) generally have small thicknesses, for example lower than 10 nm. The conversion efficiency of a conductive track 20 according to the invention (i.e. thick), for generating orbital moment currents, is therefore ten to one hundred times greater than that of an SOT track.

In addition, a greater thickness reduces the total resistance of the conductive track 20 and therefore increases the reading speed of the device 1.

The thickness h20 of the conductive track 20 of the device 1 is in an embodiment strictly greater than 10 nm and in an embodiment greater than or equal to 20 nm or even greater than or equal to 50 nm. It is additionally contemplatable and highly advantageous for the thickness h20 of the track 20 to be equal to 100 nm.

In order for the orbital moment currents generated by the track 20 to reach the spacer 30, it is advantageous for the track 20 also to have a sufficient mean orbital moment diffusion length δ₂₀ (also called “mean diffusion length”). For example, it is desirable that this diffusion length δ₂₀ is greater than or equal to the thickness h20 of the track 20. Hence, the entire orbital moment current generated can reach the spacer 30. However, if this length δ₂₀ is lower than the thickness h20 of the track 20, only a portion of this orbital moment current is likely to reach the spacer 30. This portion is proportional to δ₂₀/h20.

The conductive track 20 also has in an embodiment a weak spin-orbit coupling. Thus, the generation and propagation of orbital moment currents in the track 20 is only slightly disturbed by spin currents. By weak spin-orbit coupling, it is meant a coupling lower than 136 eV, i.e. 10 Ry (the Rydberg unit, commonly used to express spin-orbit coupling, is equal to 13.6 eV); and in an embodiment lower than 13.6 eV, i.e. 1 Ry. Materials commonly used to form SOT tracks, for example heavy metals, have spin-orbit couplings exceeding 680 eV, i.e. 50 Ry. For example, platinum has a spin-orbit coupling of about 1088 eV, or 80 Ry.

The spin-orbit coupling can also be expressed relative to a known spin-orbit coupling for a common material. For example, being expressed relative to platinum, the conductive track 20 in an embodiment has a spin-orbit coupling lower than 12% of the spin-orbit coupling of platinum, or even lower than 1.2% of the spin-orbit coupling of platinum.

Materials with interesting conversion rates, sufficient electrical conductivity, low spin-orbit coupling and long diffusion lengths are, for example: titanium, vanadium, chromium, manganese, copper, zirconium, niobium, molybdenum, ruthenium, aluminium, polycrystalline silicon, tungsten in the alpha phase (called “α-W”, to be distinguished from the beta phase called “β-W” which exhibits significant spin-orbit coupling). The conductive track 20 can therefore be formed from one of these materials or an alloy of these materials. It is also advantageous, to facilitate manufacture of the device 1, to make the conductive track 20 from a nitride of these materials or from a hardened alloy of these materials.

The conductive track 20 is in direct contact with the spacer 30 to effectively inject the orbital moment current into the spacer 30. It is advantageous that the conductive track 20 and the spacer 30 therefore share a large, good quality common interface. The spacer 30 and track 20 can beneficially be made from a same material to reduce interface effects. They can also be deposited successively, for example under vacuum or neutral atmosphere, in order to retain an optimum surface state between the spacer 30 and the track 20.

FIG. 2 schematically shows a second embodiment of the device 1. Unlike the embodiment of FIG. 1, the conductive track 20 does not extend in parallel to the layer plane {X; Y}. Instead, it is L-shaped (alternatively, it can also be double-L-shaped, in other words U-shaped). The conductive track 20 has two consecutive portions. A first, so-called parallel, portion 21, extending perpendicularly to the layer plane {X; Y} and in direct contact with the spacer 30. A second, so-called perpendicular, portion 22, extending perpendicularly to the layer plane {X; Y}, in other words along the vertical axis Z. In this example, the perpendicular portion 22 extends as an extension of one flank 30a of the spacer 30. It could also be laterally distant from the spacer 30.

FIG. 3 schematically shows a third embodiment of the device 1. Unlike the embodiment of FIG. 1, the second and third terminals 42, 43 frame the top of the spacer 30 in order to shorten length of the conductive track 20. In this example, the spacer 30 comprises an electrically insulating layer 60 extending against its flank 30a. The purpose of the insulating layer 60 is to electrically insulate the spacer 30 from the second and third terminals 42, 43. In this way the terminals 42, 43 are only connected to the conductive track 20. The insulating layer 60 may cover only a portion of the flank 30a of the spacer 30. It is at least the flank portion facing the second and third terminals 42, 43. The insulating layer may also extend against the flank 10a of the tunnel junction 10, as an extension of the flank 30a of the spacer 30.

The insulating layer 60 can be formed by oxidation of the flank 30a of the spacer 30. It can also be formed by conformally depositing a dielectric or by conformally depositing a semiconductor which is subsequently oxidised. Care must be taken, however, to protect the upper surface of the spacer 30 on which the conductive track 20 makes contact. For this, the insulating layer 60 can be formed after the conductive track 20 has been formed.

In the example illustrated in FIG. 3, the second and third terminals 42, 43, pressed against the spacer 30 (and herein against the insulating layer 60), form a cavity (or trench) at the bottom of which the conductive track 20 extends, connecting both terminals. Each of the terminals 42, 43 has a wall 42a, 43a extending as an extension of part of the flank 30a of the spacer 30. These walls 42a, 43a thus form the walls of the cavity (or trench).

Alternatively, both terminals 42, 43 can be disposed on either side of the spacer 30, flush with the top of the spacer 30. The conductive track 20 then extends in a planar way over both terminals 42, 43 and the top of the spacer 30.

FIG. 4 sets forth an embodiment wherein the device 1 is in a so-called “top pinned” configuration.

Unlike the embodiment of FIG. 1, wherein the device 1 is in a so-called “bottom pinned” configuration, the spacer 30 is disposed between the tunnel junction 10 and the substrate 5. In a top pinned configuration, the tunnel junction 10 rests on the spacer 30 via its free layer 11. This means that the reference layer 13 is disposed above the free layer 11.

In this example, the conductive track 20 and the spacer 30 are formed from the same material. The absence of an interface between both materials improves the efficiency of the device 1.

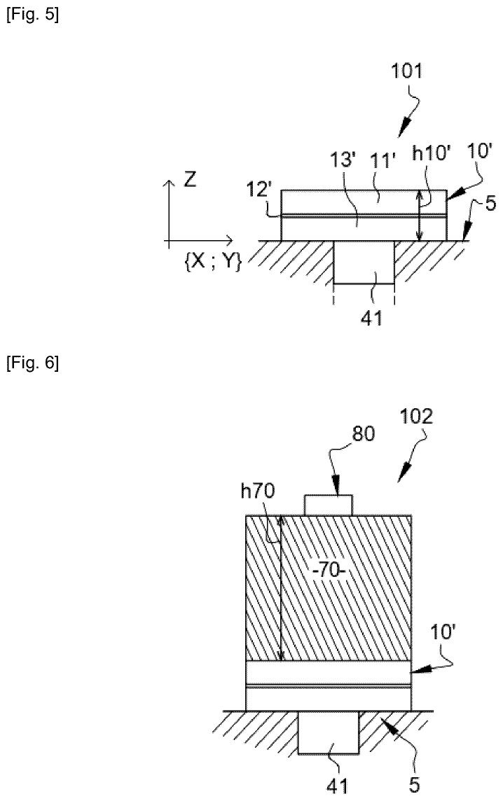

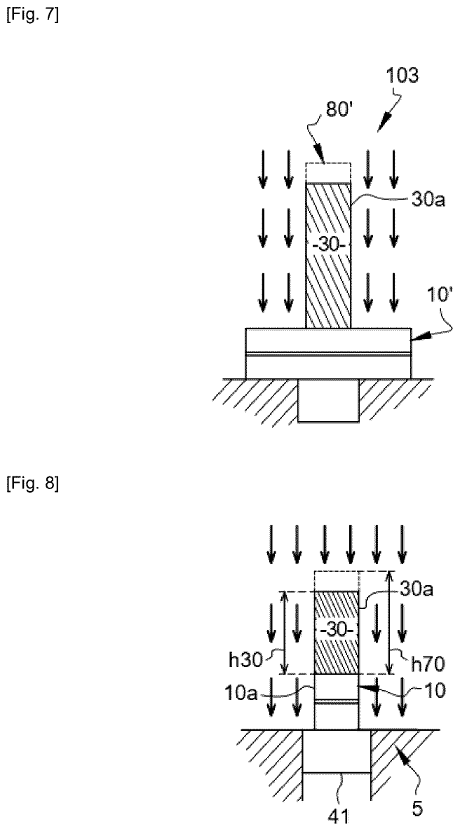

FIGS. 5 to 10 schematically show a mode of implementation of a manufacturing method for obtaining the device 1 of FIG. 1, i.e. in a bottom pinned configuration. The manufacturing method can be made using a substrate 5, as set forth in FIG. 5, an upper surface of which forms the layer plane {X; Y}. The substrate 5 is made of Si, for example. In this mode of implementation, a first terminal 41 partially passes through the substrate 5 and opens onto its surface via an opening. The top of the first terminal 41 is flush with the upper surface of the substrate 5. The first terminal 41 may be a via, a “BEOL” (Back End Of Line) type plug or even a track partly extending into the substrate 5.

A first step in the method, illustrated by FIG. 4, consists in depositing 101 a magnetic stack 10′ onto the substrate 5. This stack comprises first, second and third layers 11′, 12′, 13′ which are to form the layers 11, 12, 13 of the tunnel junction 10 of FIG. 1. This depositing 101 comprises, for example, depositing two magnetic layers 11′, 13′ separated by an insulating layer 12′. The first magnetic layer 11′ is for example to form, once delimited, the free layer 11 of the tunnel junction 10.

The method can also include initially depositing layers intended to form a seed layer and/or a synthetic antiferromagnet (not represented in this figure), as discussed previously.

The method then comprises depositing 102 a conductive layer intended to form the spacer 30, illustrated in FIG. 5. The conductive layer 70 can be formed from a single material (or alloy of materials). In other words, it does not include a sub-layer or inclusions. In this case, the conductive layer 70 comprises a material with a long orbital moment current diffusion length, as discussed above. This material also has a material whose spin-orbit coupling is strictly lower than 136 eV, i.e. 10 Ry, or even 13.6 eV, i.e. 1 Ry. Conductive layer 70 is made, for example, from the materials described with reference to spacer 30.

In this example, the conductive layer 70 is deposited directly in contact with the magnetic stack 10′ and more particularly with the first magnetic layer 11′. In this case, depositing 102 can be performed by means of a physical deposition method. Other deposition methods may be contemplated, such as chemical deposition.

Alternatively, before depositing the conductive layer 70, the manufacturing method can include a step of depositing, onto the magnetic stack 10′, a thin layer (lower than 10 nm) with a high spin-orbit coupling, greater than 680 eV, i.e. 50 Ry, so as to form, after delimitation, a conversion layer. The conductive layer 70 is then deposited directly in contact with this layer, intended to form the conversion layer.

The stack 10′ and the conductive layer 70 (and the conversion layer if applicable) are beneficially deposited in successive steps. In this way, the surface state of the first, freshly deposited magnetic layer 11′ can be protected by the conductive layer 70 (or the conversion layer). The atmosphere in which these different layers are deposited is thus retained. The deposition operations are performed, for example, under vacuum or in a neutral gas atmosphere, with no venting between these deposition operations. Thus, the quality of the surface state of the first magnetic layer 11′ is retained and protected by the conductive layer 70. This deposition also makes it possible to ensure a very good quality interface between the free layer 11 of the tunnel junction 10 and the spacer 30.

The method may include annealing, made after depositing 101, 102 the magnetic stack 10′ and the conductive layer 70. For example, when the first magnetic layer 11′ of the stack 10′ is made of CoFeB and the insulating layer 12′ is made of MgO, annealing improves the interface between these two layers and increases the out-of-plane magnetic anisotropy between these two layers 11′, 12′. This can result in a free layer 11 with perpendicular anisotropy after delimiting the junction. Annealing can also improve the interface between the first magnetic layer 11′ and the conductive layer 70. Annealing can also be made after etching the conductive layer 70 and the magnetic stack 10′.

FIG. 6 shows a step of etching 103 the conductive layer 70 so as to form the spacer 30. This etching is made anisotropically through a first etch mask 80. Etching 103 can be stopped on the magnetic stack 10′. The first mask 80, made of resin for example, is formed by photolithography on the spacer 30.

Etching 103 the conductive layer 70 is beneficially aligned with the first terminal 41 so that the device 1 is correctly connected to the terminal 41.

FIG. 7 shows a step 104 of etching the magnetic stack 10′ to form the tunnel junction 10. This delimitation 104 is performed by anisotropic etching employing the spacer 30 obtained in the preceding step. Etching is stopped on the substrate 5. The stack 10′ is etched as an extension of the spacer 30. Etching makes it possible to retain a very good quality interface between the first magnetic layer 11′ (now forming the free layer 11) and the spacer 30.

At the end of the step 104 of etching the magnetic stack 10′, the spacer 30 has its final thickness h30. The initial thickness h70 of the conductive layer 70 is beneficially selected so that the spacer 30 has the correct final thickness h30 at the end of etching. Thus, the orbital moment currents can reach the tunnel junction 10.

The conductive layer 70 is deposited with an initial thickness h70, measured perpendicularly to the substrate 5. This thickness h70 depends on the etch rate of the material used to form this layer 70 as well as the etch rate of the magnetic stack 10′. Generally speaking, by “etch rate”, it is meant a rate at which a layer is etched. This etch rate is assessed under reproducible etching conditions. The comparison between two etch rates is therefore made for identical etching conditions. Indeed, the etch rate is highly dependent on the species or species used as the etching element or on the composition of the fluids or gases used to perform etching. In addition, as the magnetic stack 10′ may comprise layers with different etch rates, the etch rate considered is the mean rate of the etch rates of the layers of the stack 10′.

More particularly, the initial thickness h70 of the conductive layer 70 may depend on:
the etch rate v70 of the conductive layer 70 (and especially the mean etch rate if this is not homogeneous);
the etch rate v10′ and the thickness h10′ of the stack 10′; and
the mean diffusion length of the spacer 30 (which may correspond to the diffusion length of the conductive layer 70).

The initial thickness h70 can be substantially equal to: h70≈h10′×v70/v10′+h30

By “approximately equal” or the sign “≈”, it is meant equal to within 20%, or even 10%.

Since the thickness h30 of the spacer 30 must be lower than the diffusion length δ to allow an effect on the free layer, the initial thickness h70 of the conductive layer is in an embodiment lower than: h70<h10′×v70/v10′+δ

In this way, the final thickness h30 of the spacer 30 guarantees propagation of the orbital moment current generated by the conductive track 20 towards the tunnel junction 10. The etch rate can vary within the conductive layer as a function of its thickness (for example when it is a multi-layer). Therefore, calculating the initial thickness h70 of the conductive layer 70 to obtain a final thickness h30 of the spacer 30 that is lower than the mean orbital moment diffusion length ensures the correct operation of the device 1 manufactured.

This inequality assumes that at the end of etching 103 of the conductive layer 70, the first mask 80 is completely removed. If a remnant of the first mask is retained after this step, the etch rates and/or height of the conductive layer 70 are beneficially adjusted to take account of this remnant.

Once delimited, the magnetic layers 11 and 13 of the tunnel junction 10 can have their final, for example perpendicular or planar, anisotropies.

In order to limit the initial height h70 of the spacer 30, to avoid the risk of it collapsing during etching, it is beneficially selected to be harder than the magnetic stack 10′. By “harder”, it is meant that it has an etch rate lower than the etch rate of the magnetic stack 10′. Thus, the magnetic stack 10′ is etched faster than the spacer 30 and the conductive layer can have an initial thickness h70 close to the final thickness h30 of the spacer 30.

Furthermore, the shape of the spacer 30, and in particular its width or diameter, measured in parallel to the layer plane {X; Y}, is better controlled when the conductive layer has a smaller initial thickness h70, close to the final thickness h30 of the spacer 30. Thus, the conductive layer 70 has in an embodiment an etch rate lower than 90% of the etch rate of the magnetic stack 10′, or even lower than 50% of the etch rate of the magnetic stack 10 and, in an embodiment, lower than 20% of the etch rate of the magnetic stack 10′.

Conductive layer 70 can be made from a hardened alloy of titanium, vanadium, chromium, manganese, copper, zirconium, niobium, molybdenum, ruthenium, aluminium, polycrystalline silicon or even α-W tungsten. It can also be a nitride of these materials.

beneficially, the conductive layer 70 is a multi-layer comprising a first sub-layer and a second sub-layer. The first layer extends against the magnetic stack 10′. The first sub-layer is hard, i.e. it has an etch rate lower than the etch rate of the magnetic stack 10′ and also lower than the etch rate of the second sub-layer. The etch rates of the first and second sub-layers and of the magnetic stack are considered for identical etching conditions. Combining different etch rates therefore makes it possible to deposit a conductive layer 70 with a smaller initial thickness h70 (before etching the spacer or delimiting the magnetic stack). Indeed, the first hard sub-layer makes it possible to reduce etch rate of the conductive layer 70. This results in reducing the risk of the spacer 30 collapsing before or during etching of the magnetic stack 10′.

Orbital moment currents can be influenced by the presence of interfaces. To avoid the proliferation of interfaces, the thickness of the first sub-layer can be selected so that the first sub-layer is completely removed once the magnetic stack 10′ has been etched. The first sub-layer thus acts as a temporary etch mask, making it possible to reduce etch rate of the conductive layer (or even of the spacer 30), without remaining in the final device 1.

FIG. 8 schematically shows forming 105 the conductive track 20. It first comprises a sub-step of depositing a dielectric layer 90 flush with the top of the spacer 30 (i.e. the free part of the spacer 30). This dielectric layer 90 is deposited, for example, covering the spacer 30. The dielectric layer 90 is then planarised, for example by means of mechanical and/or chemical polishing, stopping at the top of the spacer 30. This step releases the top of the spacer from the dielectric layer 90. The dielectric layer 90 comprises SiO₂ for example. A sub-step of depositing the material intended to form the conductive track 20 is deposited onto the spacer 30 and the dielectric layer 90. The deposition is made through a mask or the layer is etched through a mask, or even the material can be transferred to form the conductive track 20.

In FIG. 8, the conductive track 20 extends flat (i.e. in parallel to the layer plane), partly against the spacer 30 and partly over the dielectric layer 90. This configuration provides sufficient accumulation of orbital moments on the surface of the conductive track 20 to allow them to be injected into the spacer 30.

The material used to form the conductive track 20 is able to generate an orbital moment current and also has a low spin-orbit coupling, for example lower than 136 eV, i.e. 10 Ry, or even lower than 13.6 eV, i.e. 1 Ry. It is made, for example, from titanium, vanadium, chromium, manganese, copper, zirconium, niobium, molybdenum, ruthenium, aluminium, polycrystalline silicon or even α-W tungsten or an alloy of these materials.

FIG. 9 schematically shows forming 106 the second and third terminals 42, 43. They are obtained by depositing a metal through a mask so as to each connect one end of the conductive track 20. The second and third terminals 42, 43 can also take the form of vias rising from the substrate 5 to the conductive track 20.

To form the device 1 of FIG. 2, the step of forming the conductive track 20 differs from the step illustrated in FIG. 8 in that the dielectric layer 90 is not planarised by polishing. Instead, it has a different height on either side of the spacer 30. On one side of the spacer 30 only, the dielectric layer 90 has a greater height than the spacer 30. The dielectric layer 90 thus provides a surface 91 (or “flank”) extending as an extension of the flank 30a of the spacer 30, over which a portion 22 of the conductive track 20 can extend. The difference in height of the dielectric layer 90 is achieved, for example, by etching part of the dielectric layer 90 with stopping on the top of the spacer 30 so that the dielectric layer 90 has this flank 91 extending perpendicularly to the layer plane {X; Y} and disposed as an extension of a part of a flank 30a of the spacer 30. The conductive track 20 can then be made by conformal deposition to form a first portion 21 extending against the spacer 30 and a second portion 22 extending against the flank 91 of the dielectric layer.

The conductive track 20 is therefore L-shaped, with the perpendicular portion 22 extending in line with the spacer 30 by deviating from the spacer 30. It especially has a corner joining the parallel portion 21 with the perpendicular portion 22.

To form the device 1 of FIG. 3, the steps of forming the conductive track 20 and of forming the second and third terminals 42, 43 are modified and reversed.

Firstly, the manufacturing method comprises an additional step of forming the insulating layer 60 on the flank 30a of the spacer 30. This insulating layer 60 is obtained, for example, by conformally depositing an oxide film. It can also be obtained by conformally depositing a semiconductor film which is secondly thermally oxidised. Anisotropic etching or chemical and physical planarisation of this conformal film makes it possible to clear the upper face of the spacer 30 on which the conductive track 20 is to make contact.

Secondly, the first sub-step (105) of forming the conductive track 20, which consists in depositing the dielectric layer 90, is performed in such a way as to clear a portion of the height of the spacer 30. Stated differently, the resulting dielectric layer does not reach or exceed the top of the spacer 30.

The second and third terminals 42, 43 are then formed so as to create a first wall 42a and a second wall 43a respectively, disposed on either side of the spacer 30 and forming a trench in vertical alignment with the spacer 30, the cleared portion of the spacer 30 forming a bottom of the trench. The second and third terminals 42, 43 are for example formed on either side of the spacer 30, resting against the insulating layer 60. The terminals 42, 43 are shaped so as to protrude from the spacer 30. In other words, they form the walls 52a, 43a of the trench of which the spacer 30 is the bottom.

Finally, the second sub-step 105 of forming the conductive track 20, consisting in depositing the material intended to form the conductive track 20, is performed in the cavity formed by the terminals 42, 43. The conductive track 20 extends in parallel to the layer plane {X; Y} and against the cleared portion of the spacer 30, by electrically connecting the first and second terminals.

Alternatively, the second and third terminals can be formed level with the spacer 30, i.e. flush with the top of the spacer 30 on the spacer 30 and the dielectric layer 90. Depositing the conductive track 20 produces a track parallel to the layer plane.

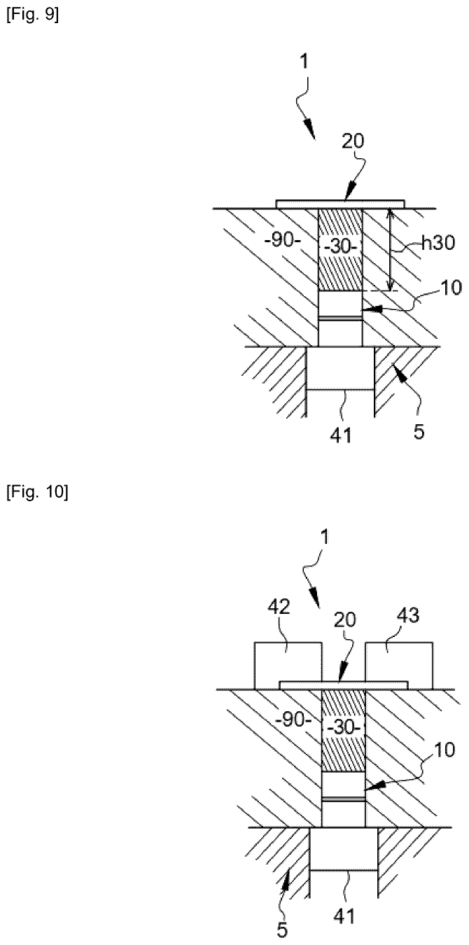

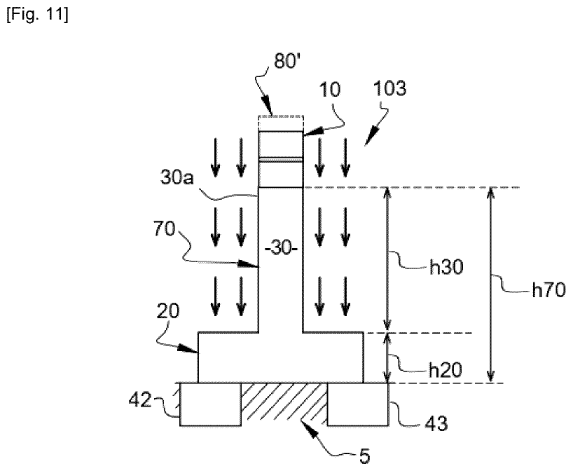

FIG. 11 schematically shows a mode of implementation of a manufacturing method for obtaining the device 1 of FIG. 4, i.e. in a top pinned configuration. The manufacturing method can be made from a substrate 5, as set forth in FIG. 5.

In order to obtain the top pinned configuration, i.e. the reverse of the bottom pinned configuration, the steps of the manufacturing method are reversed.

Initially, the method comprises depositing 102 the conductive layer 70 onto the substrate 5. Since the spacer 30 and the track 20 are formed from the conductive layer 70, its initial thickness h70 is equal to the sum of the thickness h30 of the targeted spacer 30 and the thickness h20 of the conductive track 20. Conductive layer 70 is made from the aforementioned materials. It must especially have a mean spin-orbit coupling strictly lower than 136 eV, a mean orbital moment diffusion length strictly greater than 10 nm and be able to generate an orbital moment current from a charge current.

Initially, the method comprises depositing 101 the magnetic stack 10′ onto a conductive layer 70. The magnetic stack 10′ is similar to the stack of FIGS. 5 to 10 except that its orientation is reversed relative to these figures. The magnetic layer for forming the free layer 11 is disposed facing the conductive layer 70.

The method then comprises etching 104 the magnetic stack 10′ to form the magnetic tunnel junction 10. This etching can be formed by employing an etch mask.

The method further comprises partially etching 103 the conductive layer 70 through the etch mask employed to etch the magnetic stack 10′. This partial etching 103 delimits the conductive spacer 30 in vertical alignment with the tunnel junction 10. It also makes it possible to retain part of the conductive layer 70 forming the conductive track 20 in direct contact with the conductive spacer 30.

In one alternative, the tunnel junction 10 can be employed as an etch mask to make all or part of partially etching 103 the conductive layer 70.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A magnetic device comprising:
a magnetic tunnel junction;
a conductive spacer; and
a conductive track,
the conductive spacer extending as an extension of the magnetic tunnel junction along a direction perpendicular to a plane, the plane a layer plane, the conductive spacer being disposed between the magnetic tunnel junction and the conductive track, the conductive spacer being in direct contact with the conductive track, the conductive track comprising at least one portion extending in parallel to the layer plane and directly against the conductive spacer, the conductive spacer having: a mean spin-orbit coupling strictly lower than 136 eV; a mean orbital moment diffusion length strictly greater than 10 nm; a thickness lower than the mean orbital moment diffusion length, the conductive track being able to generate an orbital moment current from a charge current and having a spin-orbit coupling strictly lower than 136 eV.

2. The device according to claim 1, wherein the conductive spacer has a thickness greater than or equal to 20 nm.

3. The device according to claim 1, wherein the mean spin-orbit coupling of the conductive spacer is strictly lower than 13.6 eV.

4. The device according to claim 1, wherein the conductive track has a thickness strictly greater than 10 nm.

5. The device according to claim 1, wherein the mean spin-orbit coupling of the conductive track is strictly lower than 13.6 eV.

6. The device according to claim 1, wherein the conductive track is able to convert at least 10% of the charge current into orbital moment current.

7. The device according to claim 1, comprising a substrate, the magnetic tunnel junction being disposed between the conductive spacer and the substrate.

8. The device according to claim 1, comprising a substrate, the conductive spacer being disposed between the magnetic tunnel junction and the substrate.

9. The device according to claim 1, wherein the conductive spacer is in direct contact with the magnetic tunnel junction.

10. The device according to claim 1, comprising an additional conversion layer, having a spin-orbit coupling greater than 680 eV, disposed between the magnetic tunnel junction and the conductive spacer, the conversion layer extending directly against the magnetic tunnel junction and directly against the conductive spacer.

11. The device according to claim 10, wherein the conversion layer has a thickness strictly lower than 10 nm.

12. A method for manufacturing a magnetic device comprising:
depositing a magnetic stack extending in parallel to a layer plane and intended to form, after etching, a magnetic tunnel junction;
depositing a conductive layer onto the magnetic stack;
anisotropically etching the conductive layer to form a conductive spacer;
etching the magnetic stack to form a magnetic tunnel junction, the etching being made by employing the conductive spacer as an etch mask, the conductive spacer having, after etching the magnetic stack: a mean spin-orbit coupling strictly lower than 136 eV; a mean orbital moment diffusion length strictly greater than 10 nm; and a thickness lower than the mean orbital moment diffusion length; and
forming a conductive track in direct contact with the conductive spacer from a material able to generate an orbital moment current from a charge current and having a spin-orbit coupling strictly equal to 136 eV, the conductive track comprising at least one portion extending in parallel to the layer plane and directly against the conductive spacer.

13. The method according to claim 12, wherein the conductive layer has an initial thickness as a function of: the thickness of the magnetic stack; the etch rate of the magnetic stack; the etch rate of the conductive layer; and the mean orbital moment diffusion length of the conductive spacer after etching of the magnetic stack, the etch rate of the magnetic stack and the etch rate of the conductive layer being considered for identical etching conditions.

14. The method according to claim 13, wherein the conductive spacer has an etch rate lower than the etch rate of the magnetic stack, the etch rates of the conductive spacer and of the magnetic stack being considered for identical etching conditions.

15. The method according to claim 13, wherein the conductive layer is a multi-layer comprising a first sub-layer and a second sub-layer, the second sub-layer being disposed between the first sub-layer and the magnetic stack, the first sublayer having an etch rate lower than the etch rate of the magnetic stack and lower than the etch rate of the second sublayer, the etch rates of the first and second sublayers and of the magnetic stack being considered for identical etching conditions.

16. The method according to claim 12, wherein forming the conductive track comprises the sub-steps of:
depositing a dielectric layer covering the conductive spacer;
etching a part of the dielectric layer with stopping on the top of the conductive spacer so that the dielectric layer has a flank extending perpendicularly to the layer plane and disposed as an extension of a part of a flank of the conductive spacer;
depositing the conductive track partly against the dielectric layer and partly against the conductive spacer, the conductive track having two consecutive portions, one of the portions forming a parallel portion, extending in parallel to the layer plane and directly against the conductive spacer, and the other of the portions forming a perpendicular portion, extending perpendicularly to the layer plane and directly against the flank of the dielectric layer.

17. The method according to claim 12, wherein forming the conductive track comprises the sub-steps of:
depositing an insulating layer against a flank of the conductive spacer;
forming a dielectric layer extending against the insulating layer while leaving a portion of the conductive spacer cleared;
forming a first conductive terminal and a second conductive terminal on the dielectric layer, on either side of the spacer, the first and second terminals being spaced apart and separated from the spacer by the insulating layer;
depositing the conductive track so that the conductive track extends in parallel to the layer plane and against the cleared portion of the spacer, by electrically connecting the first and second terminals.

18. A method for manufacturing a magnetic device comprising:
depositing a conductive layer extending in parallel to a plane forming a layer plane, the conductive layer having a mean spin-orbit coupling strictly lower 136 eV, a mean orbital moment diffusion length strictly greater than 10 nm and being able to generate an orbital moment current from a charge current;
depositing a magnetic stack onto a conductive layer, the magnetic stack being intended to form a magnetic tunnel junction after etching;
etching the magnetic stack to form a magnetic tunnel junction, the etching being made through an etch mask, partially etching the conductive layer through the etch mask to form a conductive spacer and retaining part of the conductive layer forming a conductive track in direct contact with the conductive spacer, the thickness of the conductive spacer being lower than the mean orbital moment diffusion length, the conductive track comprising at least one portion extending in parallel to the layer plane and directly against the conductive spacer.
